(19) United States
(12) Patent Application Publication
(10) Pub. No.: US 2024/0429292 A1
(43) Pub. Date: Dec. 26, 2024

(54) SEMICONDUCTOR DEVICE ISOLATION OF CONTACT AND SOURCE/DRAIN STRUCTURES

(71) Applicant: Taiwan Semiconductor Manufacturing Co., Ltd., Hsinchu (TW)

(72) Inventors: Chun-Yuan CHEN, HsinChu (TW); Huan-Chieh SU, Changhua County (TW); Kuo-Cheng CHIANG, Hsinchu County (TW); Chih-Hao WANG, Hsinchu (TW)

(73) Assignee: Taiwan Semiconductor Manufacturing Co., Ltd., Hsinchu (TW)

(21) Appl. No.: 18/489,367

(22) Filed: Oct. 18, 2023

Related U.S. Application Data
(60) Provisional application No. 63/510,159, filed on Jun. 26, 2023.

(51) Int. Cl. H01L 29/417; H01L 21/285; H01L 21/8234; H01L 27/088; H01L 29/06; H01L 29/08; H01L 29/423; H01L 29/45; H01L 29/66; H01L 29/775

(52) U.S. Cl. CPC H01L 29/41733; H01L 21/28518; H01L 21/823418; H01L 21/823475; H01L 21/823481; H01L 27/088; H01L 29/0673; H01L 29/0847; H01L 29/42392; H01L 29/45; H01L 29/66439; H01L 29/775

(57) ABSTRACT

The present disclosure describes a semiconductor device having a contact structure isolated from a source/drain structure. The semiconductor structure includes a gate structure on a substrate, first and second source/drain (S/D) structures on opposite sides of the gate structure, an isolation layer on the second S/D structure, a third S/D structure adjacent to and separate from the second S/D structure, and a S/D contact structure on the isolation layer and the third S/D structure. The isolation layer separates the S/D contact structure from the second S/D structure.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a contact structure isolated from a source/drain structure, in accordance with some embodiments.

FIGS. 2A and 2B illustrate cross-sectional views of a semiconductor device having a contact structure isolated from a source/drain structure, in accordance with some embodiments.

FIG. 3 illustrates a layout of a semiconductor device having a contact structure isolated from a source/drain structure, in accordance with some embodiments.

FIG. 4 illustrates an isometric view of interconnect connections of a semiconductor device having a contact structure isolated from a source/drain structure, in accordance with some embodiments.

FIG. 5 is a flow diagram of a method for fabricating a semiconductor device having a contact structure isolated from a source/drain structure, in accordance with some embodiments.

FIGS. 6-18 illustrate isometric and cross-sectional views of a semiconductor device having a contact structure isolated from a source/drain structure at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., +1%, +2%, +3%, +4%, +5%, +10%, +20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, a first source/drain (S/D) structure of a first nanostructure transistor can be electrically connected to a second S/D structure of a second nanostructure transistor at different sides of a gate structure through contact structures, via structures, first level metal lines (M0), first level metal vias (V0), and second level metal lines (M1). However, these metal lines and metal vias can require a larger cell height and more metal interconnects, which consume a larger chip area for a semiconductor device.

Various embodiments in the present disclosure provide methods for forming a contact structure isolated from a S/D structure in a semiconductor device (e.g., a nanostructure transistor) and/or other semiconductor devices in an integrated circuit (IC). In some embodiments, first and second transistors can be formed on a substrate. The first transistor can includes first and second S/D structures and the second transistor can include a third S/D structure adjacent to the second S/D structure. An isolation layer can be formed on the second S/D structure. A S/D contact structure can be formed over the second and third S/D structures. The third S/D structure can be electrically connected to the S/D contact structure. The isolation layer can isolate the second S/D structure from the S/D contact structure. In this way, the first and third S/D structures can be electrically connected through the S/D contact structure, metal lines M0, and metal vias V0 without additional interconnects, such as metal lines M1. As a result, the cell height of the semiconductor device can be reduced with fewer metal interconnects and the chip area of the semiconductor device can be reduced by about 2% to about 6%.

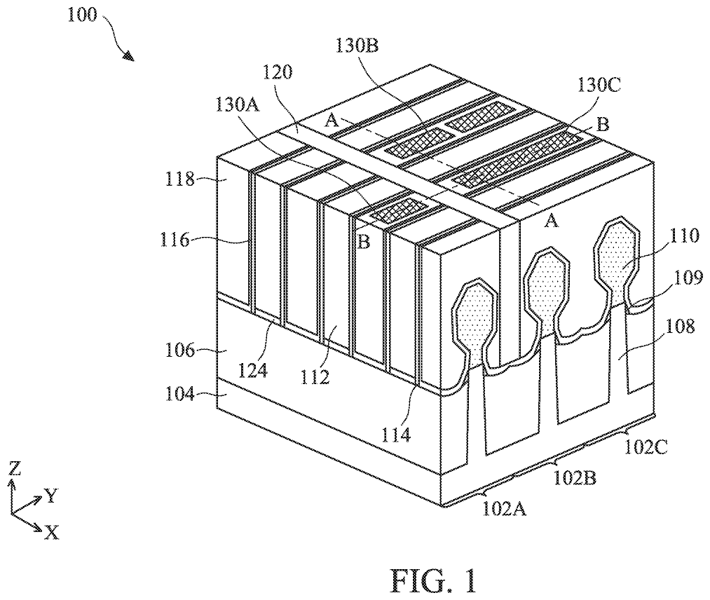

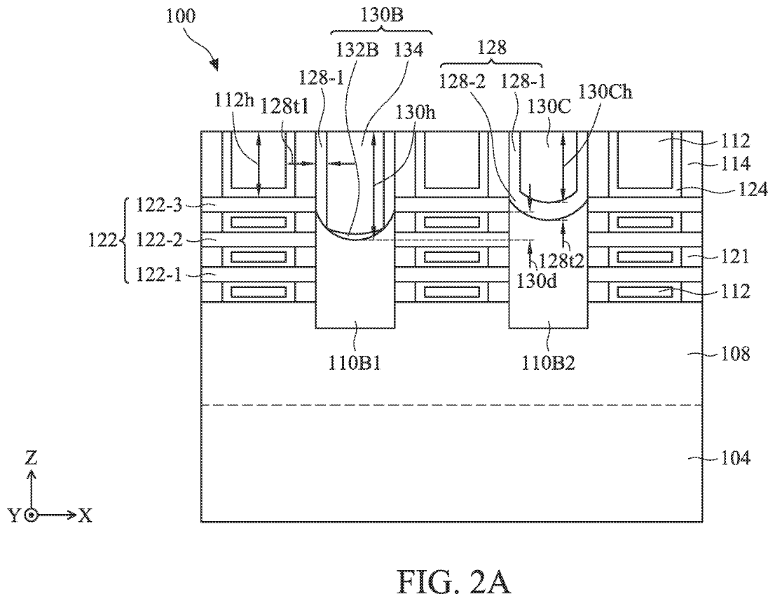

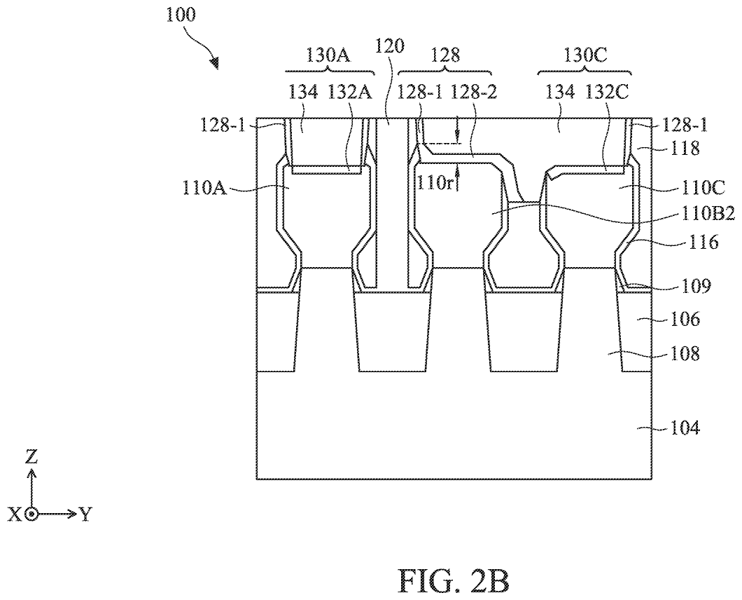

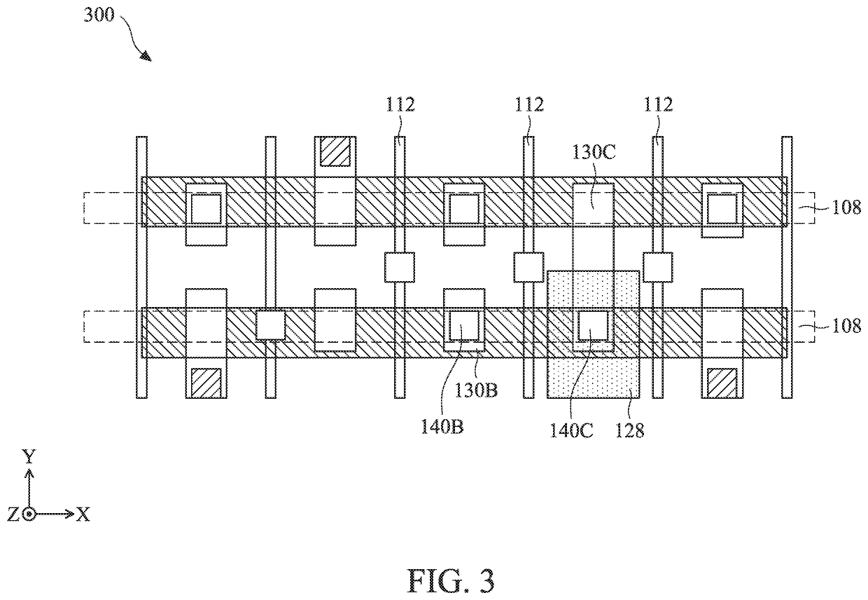

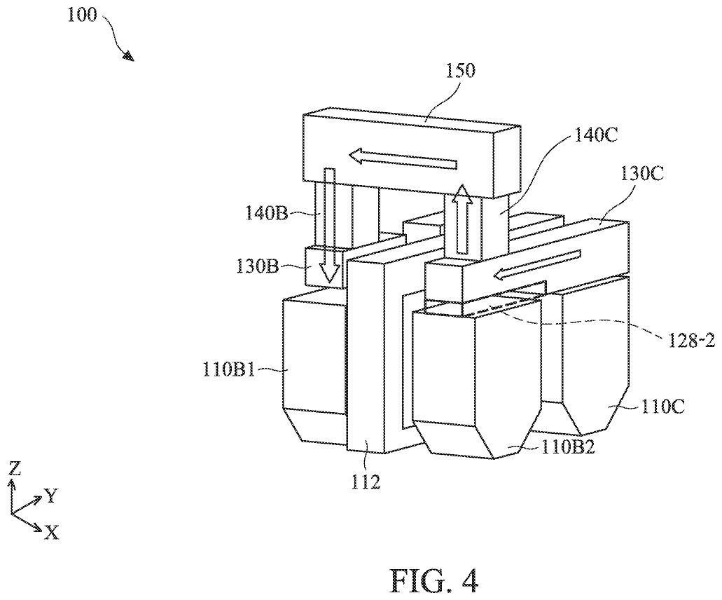

FIG. 1 illustrates an isometric view of a semiconductor device 100 having a contact structure isolated from a source/drain structure, in accordance with some embodiments. FIGS. 2A and 2B illustrate cross-sectional views of semiconductor device 100 across line A-A and line B-B shown in FIG. 1, respectively, in accordance with some embodiments. FIG. 3 illustrates a layout 300 of semiconductor device 100 having a contact structure isolated from a source/drain structure, in accordance with some embodiments. FIG. 4 illustrates an isometric view of interconnect connections of semiconductor device 100 having a contact structure isolated from a source/drain structure, in accordance with some embodiments. In some embodiments, semiconductor device 100 can include transistors 102A-102C, as shown in FIG. 1. In some embodiments, transistors 102A-102C can include nanostructure transistors. The nanostructure transistors can include the finFETs, the gate-all-around field effect transistor (GAA FET), the nanosheet transistor, the nanowire transistor, the multi-bridge channel transistor, the nano-ribbon transistor, and other similar structured transistors. The nanostructure transistors can provide a channel in a stacked nanosheet/nanowire configuration.

In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-4, semiconductor device 100 having transistors 102A-102C can be formed on a substrate 104 and can be isolated by shallow trench isolation (STI) regions 106. Each of transistors 102A-102C can include fin structures 108, sidewall spacers 109, gate dielectric layer 124, gate structures 112, gate spacers 114, S/D structures 110A, 110B1, 110B2, and 110C (collectively referred to as “S/D structures 110”), etch stop layer (ESL) 116, and interlayer dielectric (ILD) layer 118. In some embodiments, as shown in FIG. 2A, transistors 102A-102C can have nanostructures 122-1, 122-2, and 122-3 (collectively referred to as “nanostructures 122”) on fin structures 108.

Referring to FIGS. 1 and 2A-2B, substrate 104 can include a semiconductor material, such as silicon. In some embodiments, substrate 104 includes a crystalline silicon substrate (e.g., wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1 and 2A, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1 and 2A, nanostructures 122 and fin structures 108 can extend along an X-axis for transistors 102A-102C. In some embodiments, nanostructures 122 and fin structures 108 can be disposed on substrate 104. Nanostructures 122 can include a set of nanostructures 122-1, 122-2, and 122-3, which can be in the form of nanosheets, nanowires, or nano-ribbons. Each of nanostructures 122 can act as a channel structure and form a channel region underlying gate structures 112 of transistors 102A-102C. In some embodiments, nanostructures 122 and fin structures 108 can include semiconductor materials similar to or different from substrate 104. In some embodiments, nanostructures 122 and fin structures 108 can include silicon. In some embodiments, nanostructures 122 and fin structures 108 can include silicon germanium. The semiconductor materials of nanostructures 122 and fin structures 108 can be undoped or can be in-situ doped during their formation process. In some embodiments, as shown in FIG. 2A, nanostructures 122 under gate structures 112 can form channel regions of semiconductor device 100 and represent current carrying channel structures of semiconductor device 100. Though three layers of nanostructures 122 are shown in FIG. 2A, transistors 102A-102C can have any number of nanostructures 122.

In some embodiments, nanostructures 122 can have a thickness along a Z-axis ranging from about 5 nm to about 8 nm. In some embodiments, nanostructures 122 can have a width along a Y-axis ranging from about 15 nm to about 50 nm. In some embodiments, a spacing between adjacent nanostructures 122 along a Z-axis can range from about 8 nm to about 12 nm.

Referring to FIGS. 1 and 2A, gate dielectric layer 124 can be formed on nanostructures 122, fin structures 108, and STI regions 106. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

S/D structures 110 can be disposed on fin structures 108 and on opposing sides of gate structures 112. S/D structures 110 can function as S/D regions of transistors 102A-102C. In some embodiments, S/D structures 110 can have any geometric shape, such as a polygon, an ellipsis, and a circle. In some embodiments, S/D structures 110 can include an epitaxially-grown semiconductor material, such as silicon (e.g., the same material as substrate 104). In some embodiments, the epitaxially-grown semiconductor material can include an epitaxially-grown semiconductor material different from the material of substrate 104, such as silicon germanium and imparts a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. In some embodiments, S/D structures 110 can include one or more epitaxial layers, where each epitaxial layer can have different compositions. In some embodiments, S/D structures 110 can have a recess 110r for deposition of dielectric layer 128 and formation of S/D contact structures 130. In some embodiments, recess 110r can range from about 2 nm to about 10 nm.

In some embodiments, as shown in FIGS. 1 and 2A, gate structures 112 can be disposed on gate dielectric layer 124. In some embodiments, gate structures 112 can include one or more work function metal layers and a metal fill. The one or more work function metal layers can include work function metals to tune the threshold voltage (Vi) of transistors 102A-102C. In some embodiments, gate structures 112 for NFET and PFET devices can have the same work-function metal. In some embodiments, gate structures 112 for NFET and PFET devices can have different work-function metals. In some embodiments, as shown in FIG. 2A, each of nanostructures 122 can be wrapped around by gate structures 112, for which gate structures 112 can be referred to as “gate-all-around (GAA) structures” and transistors 102A-102C can also be referred to as “GAA FETs 102A-102C.” The one or more work function metal layers can wrap around nanostructures 122 and can include work function metals to tune the Vi of transistors 102A-102C. In some embodiments, transistors 102A-102C can include any number of work function metal layers for Vₜ tuning (e.g., ultra-low Vₜ, low Vₜ, and standard Vi). In some embodiments, as shown in FIG. 2A, gate structures 112 can have a height 112h above nanostructures 122 along a Z-axis ranging from about 10 nm to about 35 nm.

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIG. 1, gate spacers 114 can be disposed on sidewalls of gate structures 112, and sidewall spacers 109 can be disposed on sidewalls of fin structures 108. Gate spacers 114 and sidewall spacers 109 can include insulating materials, such as silicon oxide, silicon nitride, silicon oxynitride, silicon carbonitride, silicon oxycarbide, silicon oxycarbonitride, a low-k material, and a combination thereof. Gate spacers 114 and sidewall spacers 109 can include a single layer or a stack of insulating layers. Gate spacers 114 and sidewall spacers 109 can have a low-k material with a dielectric constant less than about 3.9 (e.g., about 3.5, about 3.0, or about 2.8).

ESL 116 can be disposed on STI regions 106, S/D structures 110, and sidewalls of gate spacers 114 and sidewall spacers 109. ESL 116 can be configured to protect STI regions 106, S/D structures 110, and gate structures 112 during the formation of S/D contact structures 130 on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, as shown in FIGS. 1-4, semiconductor device 100 can further include gate isolation structure 120, S/D contact structures 130A, 130B, and 130C (collectively referred to as “S/D contact structures 130”), first portion 128-1 and second portion 128-2 of dielectric layer 128 (collectively referred to as “dielectric layer 128”), metal vias 140B and 140C (collectively referred to as “metal vias 140”), and metal line 150.

Referring to FIGS. 1 and 2B, gate isolation structure 120 can be disposed on STI regions 106 and electrically isolate transistor 102A from transistors 102B and 102C. In some embodiments, as shown in FIG. 1, gate isolation structure 120 can extend through gate structures 112 and separate gate structures 112 into two portions. In some embodiments, gate isolation structure 120 can include silicon nitride, silicon oxide, and/or other suitable dielectric materials. In some embodiments, gate isolation structure 120 can include a single dielectric layer or a stack of dielectric layers. In some embodiments, gate isolation structure 120 can extend vertically through gate structures 112. In some embodiments, gate isolation structure 120 can extend into STI regions 106 (not shown).

In some embodiments, S/D contact structures 130A, 130B, and 130C can be disposed on S/D structures 110A, 110B1, 110B2, and 110C. In some embodiments, as shown in FIGS. 2A and 2B, S/D contact structures 130 can include silicide layers 132A, 132B, and 132C (collectively referred to as “silicide layers 132”) and metal contact 134. In some embodiments, silicide layers 132 can include metal silicide and can provide a lower resistance interface between metal contact 134 and S/D structures 110. Examples of metal used for forming the metal silicide include cobalt, titanium, and nickel. In some embodiments, metal contact 134 can include conductive materials, such as tungsten, aluminum, and cobalt. In some embodiments, as shown in FIG. 2A, S/D contact structures 130 can have a height 130h along a Z-axis above S/D structures 110A, 110B1 and 110C ranging from about 10 nm to about 40 nm. In some embodiments, height 130h of S/D contact structures can be equal or greater than height 112h of gate structures 112. In some embodiments, a portion of S/D contact structure 130C on dielectric layer 128-2 can be referred to as a S/D contact flyer. In some embodiments, the portion of S/D contact structure 130C on dielectric layer 128-2 can have a height 130Ch along a Z-axis ranging from about 6 nm to about 22 nm. In some embodiments, a depth difference 130d along a Z-axis between bottom surfaces of S/D contact structure 130B and second portion 128-2 of dielectric layer 128 can range from about 2 nm to about 10 nm.

In some embodiments, as shown in FIGS. 2A-2B, 3, and 4, dielectric layer 128 can be disposed on sidewalls of S/D contact structures 130 and between S/D contact structure 130C and S/D structure 110B2. In some embodiments, dielectric layer 128 can include a dielectric material, such as silicon oxycarbide, silicon carbonitride, silicon oxynitride, silicon oxynitricarbide, and a combination thereof. As shown in FIGS. 2A and 2B, dielectric layer 128 can include first portion 128-1 on sidewalls of S/D contact structures 130 and second portion 128-2 between S/D contact structure 130C and S/D structure 110B2. In some embodiments, first portion 128-1 of dielectric layer 128 on sidewalls of S/D contact structures 130 can act as S/D contact spacers and can be referred to as “S/D contact spacers 128-1.” In some embodiments, S/D contact spacers 128-1 can be uniform and can have a thickness 128t1 ranging from about 2 nm to about 5 nm. In some embodiments, second portion 128-2 of dielectric layer 128 between S/D contact structure 130C and S/D structures 110B2 can act an isolation layer and can be referred to as “S/D isolation layer 128-2.” In some embodiments, S/D isolation layer 128-2 can be conformal on S/D structure 110B2 and can have a thickness 128t2 ranging from about 2 nm to about 8 nm. In some embodiments, a ratio of height 130Ch to thickness 128t2 can range from about 3 to about 10. If the ratio is greater than about 10, thickness 128t2 is less than about 2 nm, or height 130Ch is greater than about 22 nm, S/D isolation layer 128-2 may not be able to isolate S/D contact structure 130C from S/D structure 110B2. If the ratio is less than about 3, thickness 128t2 is greater than about 8 nm, or height 130Ch is less than about 6 nm, S/D contact structure 130C may have worse electrical connection to S/D structure 110C and/or metal via 140C.

In some embodiments, as shown in FIG. 4, metal vias 140 and metal line 150 can connect S/D contact structure 130C to S/D contact structure 130B over gate structures 112. In some embodiments, metal vias 140 and metal line 150 can include any suitable conductive materials, such as tungsten, copper, aluminum, cobalt, titanium, ruthenium, titanium nitride, tantalum nitride, and other suitable conductive materials. Metal via 140C can be in contact with S/D contact structure 130C and metal via 140B can be in contact with S/D contact structure 130B. Metal line 150 can be in contact with metal vias 140B and 140C. With S/D isolation layer 128-2 isolating S/D contact structure 130C from S/D structures 110B2, S/D structures 110B1 and 110C at different sides of gate structures 112 for adjacent transistors 102B and 102C can be electrically connected through S/D contact structure 130B, metal via 140B, metal line 150, metal via 140C, and S/D contact structure 130C without additional metal interconnects. As a result, cell height of semiconductor device 100 can be reduced with fewer metal interconnects and the chip area of semiconductor device 100 can be reduced by about 2% to about 6%.

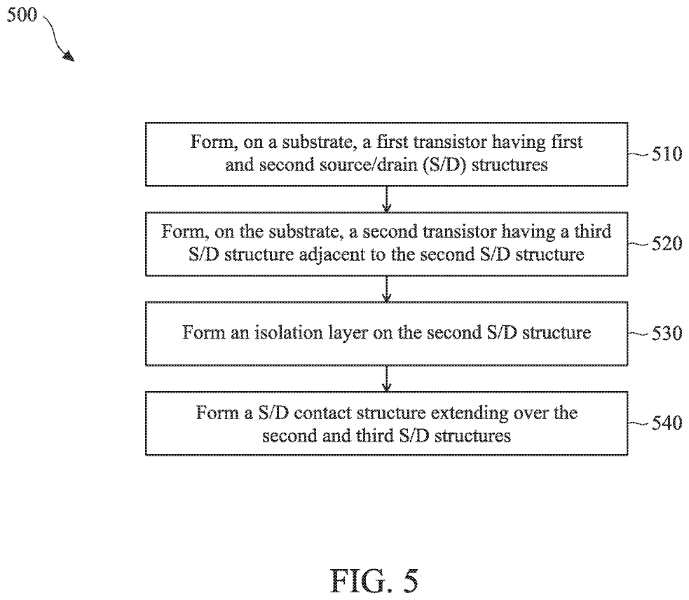

FIG. 5 is a flow diagram of a method 500 for fabricating semiconductor device 100 having a contact structure isolated from a source/drain structure, in accordance with some embodiments. Method 500 may not be limited to nanostructure transistor devices and can be applicable to other devices that would benefit from the contact structure isolated from the source/drain structure, i.e., the S/D contact flyer. Additional fabrication operations may be performed between various operations of method 500 and may be omitted merely for clarity and ease of description. Additional processes can be provided before, during, and/or after method 500; one or more of these additional processes are briefly described herein. Moreover, not all operations may be needed to perform the disclosure provided herein. Additionally, some of the operations may be performed simultaneously or in a different order than shown in FIG. 5. In some embodiments, one or more other operations may be performed in addition to or in place of the presently-described operations.

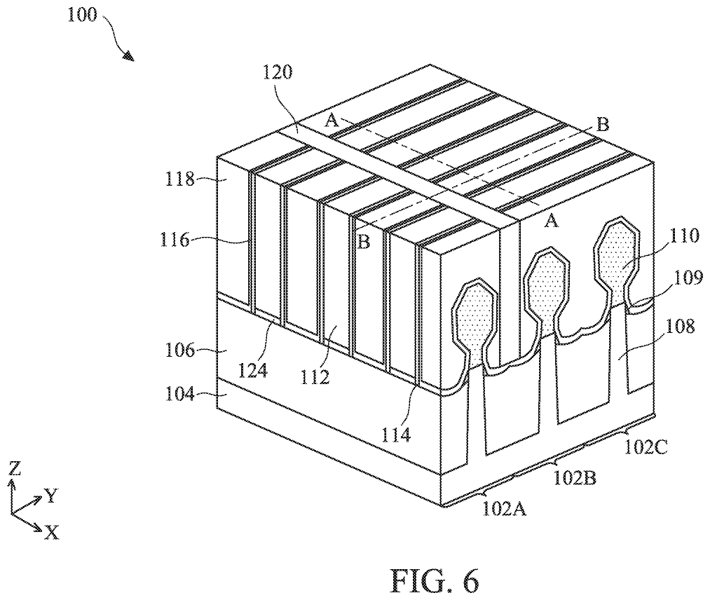

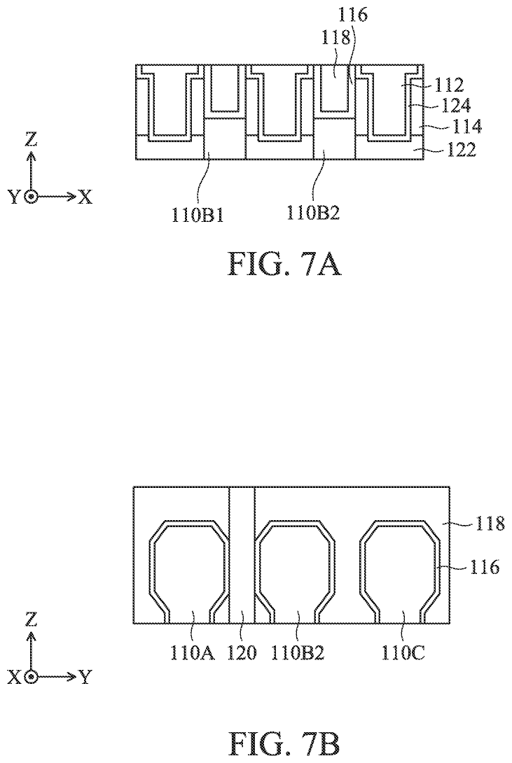

For illustrative purposes, the operations illustrated in FIG. 5 will be described with reference to the example fabrication process for fabricating semiconductor device 100 as illustrated in FIGS. 6-18. FIGS. 6-18 illustrate isometric and cross-sectional views of semiconductor device 100 having a contact structure isolated from a source/drain structure at various stages of its fabrication, in accordance with some embodiments. FIGS. 7A, 8A, 9A, 10A, 11A, 12A, and 13A illustrate partial cross-sectional views of semiconductor device 100 along line A-A as shown in FIG. 6 at various stages of its fabrication, in accordance with some embodiments. FIGS. 7B, 8B, 9B, 10B, 11B, 12B, and 13B illustrate partial cross-sectional views of semiconductor device 100 along line B-B as shown in FIG. 6 at various stages of its fabrication, in accordance with some embodiments. Elements in FIGS. 6-18 with the same annotations as elements in FIGS. 1-4 are described above.

In referring to FIG. 5, method 500 begins with operation 510 and the process of forming, on a substrate, a first transistor having first and second S/D structures. For example, as shown in FIGS. 6 and 7A-7B, transistor 102B can be formed on substrate 104. Transistor 102B can include S/D structures 110B1 and 110B2. FIG. 6 illustrates an isometric view of semiconductor device 100 having transistor 102B, in accordance with some embodiments. FIG. 7A illustrates a partial cross-sectional view of semiconductor device 100 along line A-A as shown in FIG. 6, in accordance with some embodiments. FIG. 7B illustrates a partial cross-sectional view of semiconductor device 100 along line B-B as shown in FIG. 6, in accordance with some embodiments. In some embodiments, transistor 102B can include nanostructures 122 epitaxially grown on substrate 104. In some embodiments, nanostructures 122 can be in the form of nanosheets, nanowires, or nano-ribbons. In some embodiments, nanostructures 122 can include semiconductor materials similar to or different from substrate 104. In some embodiments, gate dielectric layer 124 and gate structures 112 can be formed on nanostructures 122. In some embodiments, ESL 116 and ILD layer 118 can be formed on S/D structures 110B1 and 110B2 on opposite sides of gate structures 112. In some embodiments, gate spacers 114 can be formed on sidewalls of gate structures 112 to isolate gate structures 112 from S/D structures 110 and subsequently formed S/D contact structures 130.

Referring to FIG. 5, method 500 continues with operation 520 and the process of forming, on the substrate, a second transistor having a third S/D structure adjacent to the second S/D structure. For example, as shown in FIGS. 6 and 7A-7B, transistor 102C can be formed on substrate 104. Transistor 102C can include S/D structure 110C adjacent to S/D structure 110B2. In some embodiments, transistor 102C can further include nanostructures 122, gate dielectric layer 124, gate structures 112, ESL 116, ILD layer 118, and gate spacers 114 as described for transistor 102B. In some embodiments, nanostructure transistors 110B and 110C can be both NFETs or PFETs. In some embodiments, either of nanostructure transistors 110B and 110C can be an NFET or a PFET.

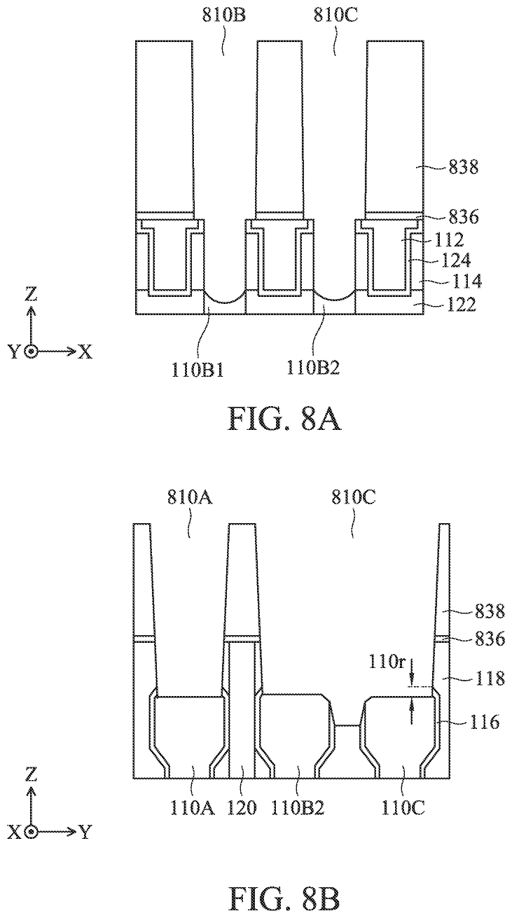

Referring to FIG. 5, in operation 530, a dielectric layer can be formed on the second S/D structure. For example, as shown in FIGS. 8A-12B, dielectric layer 128 can be formed on S/D structure 110B2. In some embodiments, dielectric layer 128 can include a first portion 128-1 on sidewalls of openings 810A-810C and a second portion 128-2 on S/D structure 110B2. In some embodiments, the formation of dielectric layer 128 can include the formation of openings on S/D structures 110, blanket deposition of a dielectric material in the openings, and selective removal of the dielectric material from top surfaces of S/D structures 110.

In some embodiments, as shown in FIGS. 8A and 8B, ESL 836 and ILD layer 838 can be blanket deposited on gate structures 112 and ILD layer 118. A patterning process and an etching process can remove a portion of ILD layer 838, ESL 836, and ILD layer 118 to form openings 810A, 810B, and 810C. In some embodiments, openings 810A, 810B, and 810C can expose and partially recessed S/D structures 110. In some embodiments, S/D structures 110 can be etched by recess 110r ranging from about 2 nm to about 10 nm to reduce contact resistance of subsequently formed S/D contact structures 130.

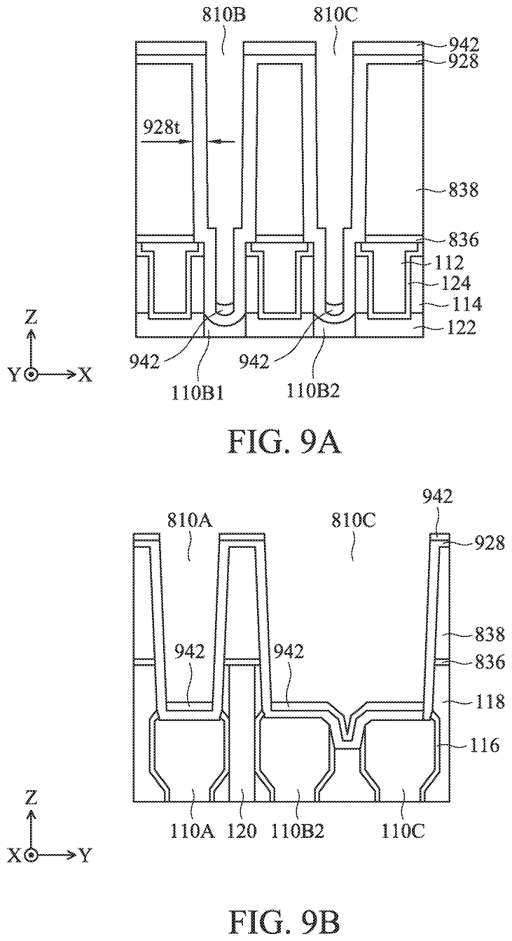

The formation of openings 810A, 810B, and 810C can be followed by the blanket deposition of a dielectric material in openings 810A, 810B, and 810C. For example, as shown in FIGS. 9A and 9B, a layer of dielectric material 928 can be blanket deposited in openings 810A, 810B, and 810C and on ILD layer 838. In some embodiments, dielectric material 928 can include silicon oxycarbide, silicon carbonitride, silicon oxynitride, silicon oxynitricarbide, or a combination thereof. In some embodiments, the layer of dielectric material 928 can have a thickness 928t ranging from about 2 nm to about 8 nm. In some embodiments, a hard mask layer 942 can be blanket deposited on the layer of dielectric material 928, as shown in FIGS. 9A and 9B. In some embodiments, hard mask layer 942 can be deposited by physical vapor deposition (PVD) or other suitable deposition method to maintain the width of openings 810A, 810B, and 810C. In some embodiments, hard mask layer 942 can be deposited at the bottoms of openings 810A, 810B, and 810C but not the sidewalls of openings 810A, 810B, and 810C.

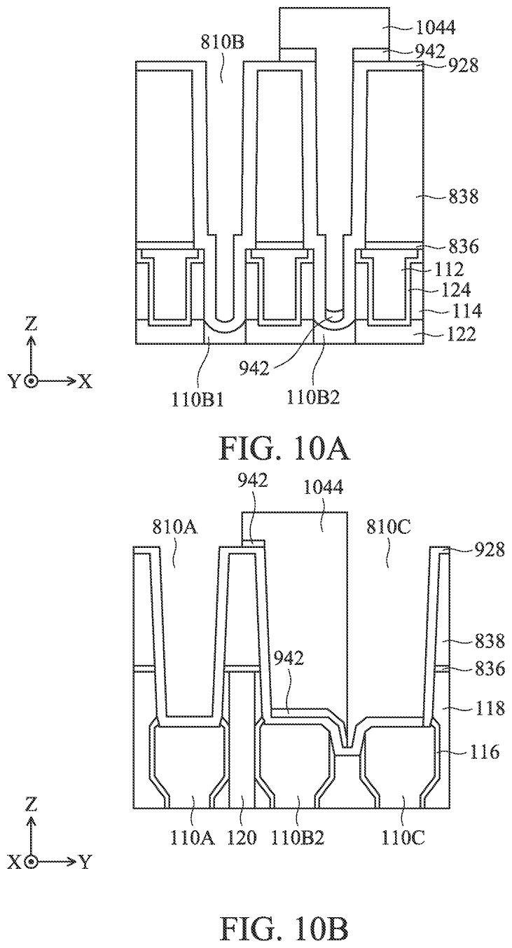

In some embodiments, as shown in FIGS. 10A and 10B, hard mask layer 942 can be patterned to selectively remove a portion of the layer of dielectric material 928. Photoresist 1044 can be blanket deposited on hard mask layer 942 and can be patterned to cover hard mask layer 942 over S/D structure 110B2. Hard mask layer 942 not covered by photoresist 1044 can be removed by a wet etching process. In some embodiments, hard mask layer 942 can be optionally trimmed before the deposition of photoresist 1044.

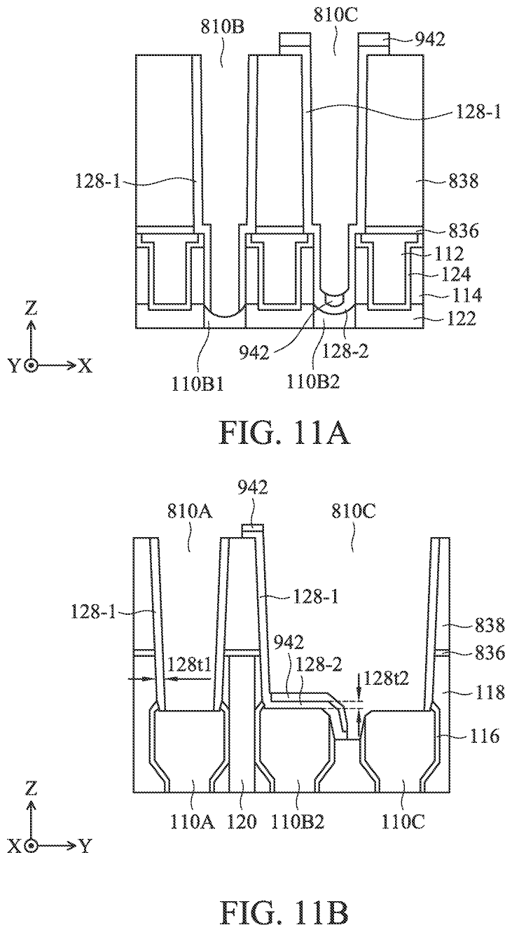

The removal of hard mask layer 942 not covered by photoresist 1044 can be followed by the selective removal of the layer of dielectric material 928. For example, as shown in FIGS. 11A and 11B, photoresist 1044 can be removed and hard mask layer 942 can protect the layer of dielectric material 928 on S/D structure 110B2 and around opening 810C. In some embodiments, an anisotropic etching process can etch the layer of dielectric material 928 outside hard mask layer 942 and form S/D contact spacers 128-1 and S/D isolation layer 128-2. In some embodiments, the anisotropic etching process can remove dielectric material 928 from top surfaces of ILD layer 838 and S/D structures 110A, 110B1, and 110C. In some embodiments, the anisotropic etching process can trim dielectric material 928 on sidewalls of openings 810A, 810B, and 810C to form S/D contact spacers 128-1. In some embodiments, S/D contact spacers 128-1 can have a thickness 128t1 ranging from about 2 nm to about 5 nm. In some embodiments, hard mask layer 942 can protect dielectric material 928 on S/D structure 110B2 during the anisotropic etching process and form S/D isolation layer 128-2 on S/D structure 110B2. In some embodiments, S/D isolation layer 128-2 can be conformally formed on top and sidewall surfaces of S/D structure 110B2. In some embodiments, S/D isolation layer 128-2 can have a thickness 128t2 ranging from about 2 nm to about 8 nm. If thickness 128t2 is less than about 2 nm, S/D isolation layer 128-2 may not be able to isolate subsequently-formed S/D contact structure 130C from S/D structure 110B2. If thickness 128t2 is greater than about 8 nm, subsequently-formed S/D contact structure 130C may have worse electrical connection to S/D structure 110C and/or metal via 140C.

Referring to FIG. 5, in operation 540, a S/D contact structure is formed extending over the second and third S/D structures. For example, as shown in FIGS. 12A-12B, 13A-13B, and 2A-2B, S/D contact structure 130C can be formed extending over S/D structures 110B2 and 110C. In some embodiments, S/D contact structure 130C can be electrically connected to S/D structure 110C. In some embodiments, S/D contact structure 130C can be isolated from S/D structure 110B2 by S/D isolation layer 128-2. In some embodiments, the formation of S/D contact structure 130C can include the formation of silicide layers 132A-132C, the formation of metal contact 134, and a chemical mechanical planarization (CMP) process.

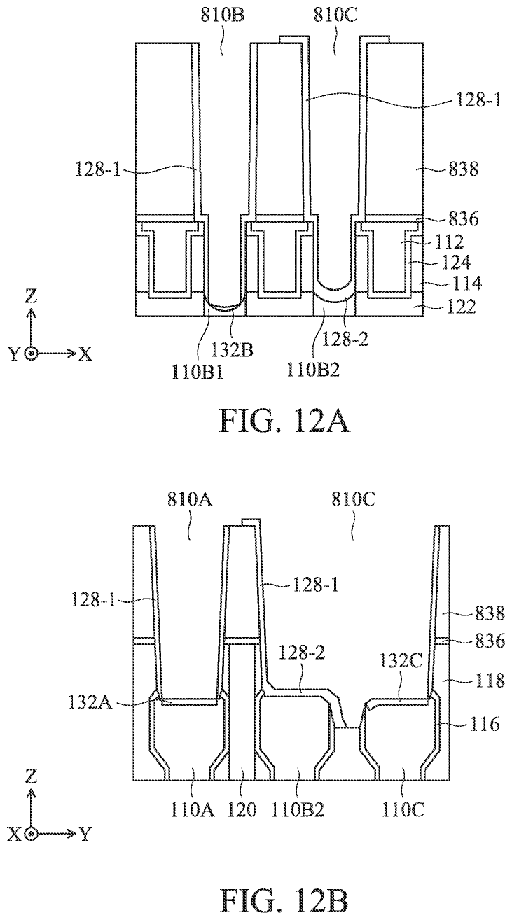

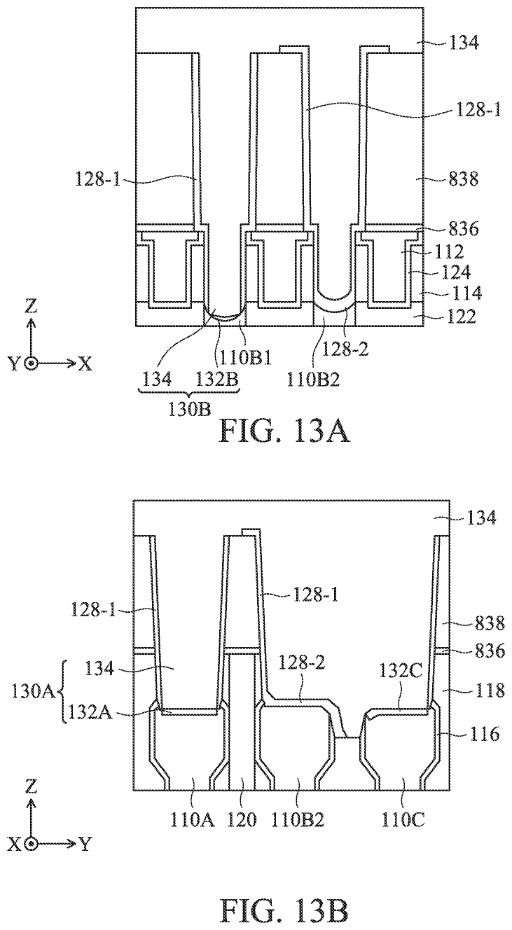

In some embodiments, as shown in FIGS. 12A and 12B, silicide layers 132A, 132B, and 132C can be formed on S/D structures 110A, 110B1, and 110C, respectively. In some embodiments, prior to the formation of silicide layers 132A-132C, hard mask layer 942 can be removed from S/D isolation layer 128-2. With S/D isolation layer 128-2 on S/D structure 110B2, silicide layers 132 may not be formed on S/D structure 110B2. In some embodiments, as shown in FIGS. 13A and 13B, the formation of silicide layers 132A-132C can be followed by the formation of metal contact 134. In some embodiments, a conductive material can be blanket deposited in openings 810A-810C and ILD layer 838 to fill openings 810A-810C. In some embodiments, the conductive material can include tungsten, aluminum, cobalt, or other suitable conductive material. In some embodiments, the formation of metal contact 134 can be followed by a CMP process to planarize top surfaces of S/D contact structures 130, S/D contact spacers 128-1, gate structures 112, gate spacers 114, gate isolation structure 120, and ILD layer 118.

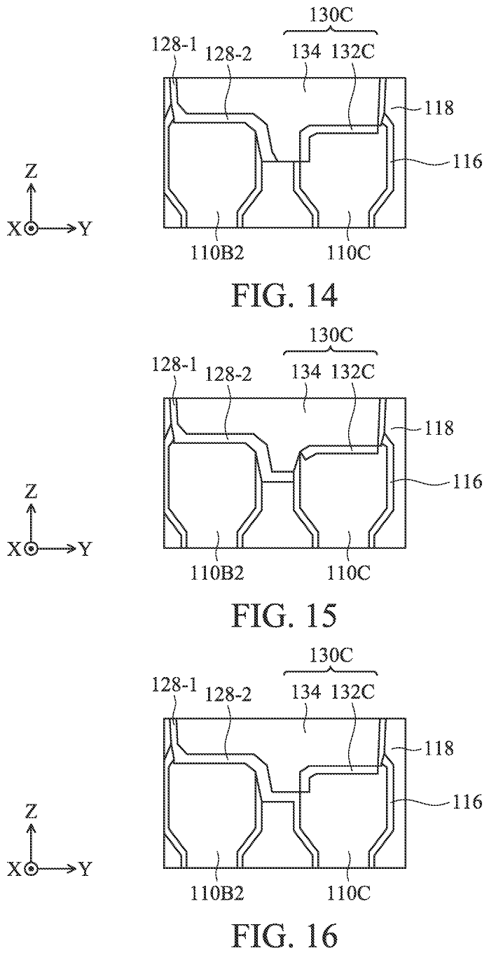

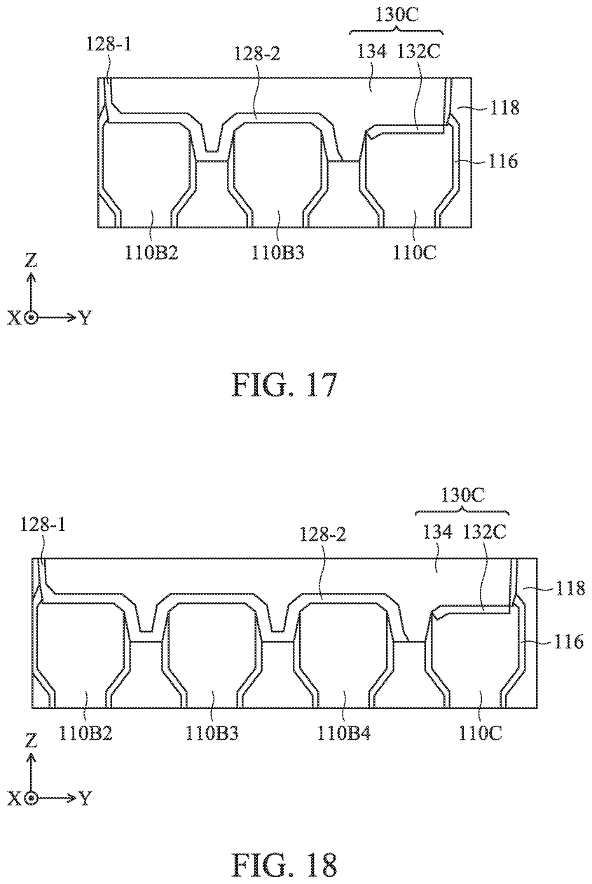

In some embodiments, as shown in FIG. 14, silicide layer 132C can cover top and sidewall surfaces of S/D structure 110C. In some embodiments, as shown in FIG. 15, silicide layer 132C can cover the top surface of S/D structure 110C and S/D isolation layer 128-2 can extend from top and sidewall surfaces of S/D structure 110B2 to sidewall surfaces of S/D structure 110C. S/D isolation layer 128-2 can be in contact with ESL 116 around S/D structure 110C. In some embodiments, as shown in FIG. 16, silicide layer 132C can cover the top and sidewall surfaces of S/D structure 110C and S/D isolation layer 128-2 can extend from the top and sidewall surfaces of S/D structure 110B2 to sidewall surfaces of S/D structure 110C. S/D isolation layer 128-2 can be in contact with ESL 116 around S/D structure 110C. In some embodiments, as shown in FIG. 17, S/D isolation layer 128-2 can extend over an additional S/D structure 110B3 between S/D structures 110B2 and 110C. In some embodiments, as shown in FIG. 18, S/D isolation layer 128-2 can extend over additional S/D structures 110B3 and 110B4 between S/D structures 110B2 and 110C. In some embodiments, S/D isolation layer 128-2 can extend over more S/D structures, such as about one S/D structures to about ten S/D structures.

In some embodiments, as shown in FIG. 4, the formation of S/D contact structures 130 can be followed by the formation of metal vias 140B and 140C, metal line 150, and additional ILD layers, which are not described in details for clarity. In some embodiments, with S/D contact structure 130C extending over S/D structures 110B2 and 110C while isolated from S/D structure 110B2 by S/D isolation layer 128-2, fewer interconnect structures are needed to electrically connect S/D structure 110B1 to S/D structure 110C. As a result, cell height of semiconductor device 100 can be reduced with fewer interconnect structures and the chip area of semiconductor device 100 can be reduced by about 2% to about 6%.

Various embodiments in the present disclosure provide example methods for forming S/D contact structure 130C isolated from S/D structure 110B2 in semiconductor device 100. In some embodiments, first and second transistors 102B and 102C can be formed on substrate 104. First transistor 102B can includes first and second S/D structures 110B1 and 110B2 and second transistor 102C can include third S/D structure 110C adjacent to second S/D structure 110B2. S/D isolation layer 128-2 can be formed on second S/D structure 110B2. S/D contact structure 130C can be formed over second and third S/D contact structures 110B2 and 110C. Third S/D structure 110C can be electrically connected to S/D contact structure 130C. S/D isolation layer 128-2 can isolate second S/D structure 110B2 from the S/D contact structure 130C. Accordingly, second S/D structure 110B1 and third S/D structure 110C can be electrically connected through S/D contact structure 130C, metal vias 140B and 140C, and metal line 150 without additional interconnects, such as metal lines M1. As a result, the cell height of semiconductor device 100 can be reduced with fewer metal interconnects and the chip area of semiconductor device 100 can be reduced.

In some embodiments, a semiconductor structure includes a gate structure on a substrate, first and second source/drain (S/D) structures on opposite sides of the gate structure, an isolation layer on the second S/D structure, a third S/D structure adjacent to and separate from the second S/D structure, and a S/D contact structure on the isolation layer and the third S/D structure. The isolation layer separates the S/D contact structure from the second S/D structure.

In some embodiments, a semiconductor device includes first and second transistor on a substrate. The first transistor includes first and second source/drain (S/D) structures. The second transistor includes a third S/D structure adjacent to the second S/D structure. The semiconductor device further includes an isolation layer on the second S/D structure and a S/D contact structure extending over the second and third S/D structures. The third S/D structure is electrically connected to the S/D contact structure. The isolation layer isolates the second S/D structure from the S/D contact structure.

In some embodiments, a method includes forming a first transistor on a substrate and forming a second transistor on the substrate. The first transistor includes first and second S/D structures. The second transistor includes a third S/D structure adjacent to the second S/D structure. The method further includes forming an isolation layer on the second S/D structure and forming a S/D contact structure extending over the second and third S/D structures. The third S/D structure is electrically connected to the S/D contact structure. The isolation layer isolates the second S/D structure from the S/D contact structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a gate structure on a substrate;
first and second source/drain (S/D) structures on opposite sides of the gate structure;
an isolation layer on the second S/D structure;
a third S/D structure adjacent to and separate from the second S/D structure; and
a S/D contact structure on the isolation layer and the third S/D structure, wherein the isolation layer separates the S/D contact structure from the second S/D structure.

2. The semiconductor structure of claim 1, wherein top surfaces of the S/D contact structure and the gate structure are coplanar.

3. The semiconductor structure of claim 1, further comprising a silicide layer on the third S/D structure, wherein the silicide layer is in contact with the third S/D structure and the S/D contact structure.

4. The semiconductor structure of claim 3, wherein a portion of the silicide layer is on sidewall surfaces of the third S/D structure.

5. The semiconductor structure of claim 1, further comprising an etch stop layer (ESL) on sidewall surfaces of the third S/D structure, wherein the isolation layer is in contact with the ESL.

6. The semiconductor structure of claim 1, further comprising a fourth S/D structure between the second and third S/D structures, wherein the isolation layer separates the fourth S/D structure and the S/D contact structure.

7. The semiconductor structure of claim 1, further comprising an additional S/D contact structure on the first S/D structure, wherein a distance between bottom surfaces of the additional S/D contact structure and the isolation layer ranges from about 2 nm to about 10 nm.

8. The semiconductor structure of claim 1, wherein a ratio of a height of the S/D contact structure on the second S/D structure to a thickness of the isolation layer ranges from about 3 to about 10.

9. The semiconductor structure of claim 1, further comprising an additional S/D contact structure on the first S/D structure and an interconnect structure over the gate structure, wherein the S/D contact structure, the interconnect structure, and the additional S/D contact structure connect the third S/D structure to the first S/D structure.

10. A semiconductor device, comprising:
a first transistor on a substrate, wherein the first transistor comprises first and second source/drain (S/D) structures;
a second transistor on the substrate, wherein the second transistor comprises a third S/D structure adjacent to the second S/D structure;
an isolation layer on the second S/D structure; and
a S/D contact structure extending over the second and third S/D structures, wherein:
the third S/D structure is electrically connected to the S/D contact structure, and
the isolation layer isolates the second S/D structure from the S/D contact structure.

11. The semiconductor device of claim 10, further comprising a silicide layer on the third S/D structure, wherein the silicide layer electrically connects the third S/D structure to the S/D contact structure.

12. The semiconductor device of claim 11, wherein a portion of the silicide layer is on sidewall surfaces of the third S/D structure.

13. The semiconductor device of claim 11, further comprising an etch stop layer (ESL) on sidewall surfaces of the third S/D structure, wherein the isolation layer is in contact with the ESL.

14. The semiconductor device of claim 10, further comprising a fourth S/D structure between the second and third S/D structures, wherein the isolation layer is on the fourth S/D structure and isolates the fourth S/D structure from the S/D contact structure.

15. The semiconductor device of claim 10, further comprising an additional S/D contact structure on the first S/D structure, wherein top surfaces of the S/D contact structure and the additional S/D contact structure are coplanar.

16. The semiconductor device of claim 10, further comprising an additional S/D contact structure on the first S/D structure and an interconnect structure over the first transistor, wherein the S/D contact structure, the interconnect structure, and the additional S/D contact structure electrically connect the third S/D structure to the first S/D structure.

17. A method, comprising:
forming a first transistor on a substrate, wherein the first transistor comprises first and second source/drain (S/D) structures;
forming a second transistor on the substrate, wherein the second transistor comprises a third S/D structure adjacent to the second S/D structure;
forming an isolation layer on the second S/D structure; and
forming a S/D contact structure extending over the second and third S/D structures, wherein:
the third S/D structure is electrically connected to the S/D contact structure, and
the isolation layer isolates the second S/D structure from the S/D contact structure.

18. The method of claim 17, further comprising forming a silicide layer on the third S/D structure, wherein the silicide layer electrically connects the third S/D structure to the S/D contact structure.

19. The method of claim 17, wherein forming the isolation layer comprises:
conformally depositing a layer of dielectric material on the second and third S/D structures; and
removing the layer of dielectric material on the third S/D structure.

20. The method of claim 17, further comprising forming an additional S/D contact structure on the first S/D structure and an interconnect structure over the first transistor, wherein the S/D contact structure, the interconnect structure, and the additional S/D contact structure electrically connect the third S/D structure to the first S/D structure.
